(19) United States
(12) Patent Application Publication
(10) Pub. No.: US 2006/0265636 A1
(43) Pub. Date: Nov. 23, 2006

(54) Optimized testing of on-chip error correction circuit

(76) Inventor: Klaus Hummler, Apex, NC (US)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/132,605

(22) Filed: May 19, 2005

(51) Int. Cl. G11C 29/00

(52) U.S. Cl. 714/800; 365/201

(57) ABSTRACT

The present invention includes a memory system with a data memory and a control circuit. The data memory has multiple memory segments, including a data memory array and a parity memory array. The control circuit is configured to receive a set of data having a plurality of bits, at least some of which are restricted so that they have the same state. The control circuit generates parity bits from the set of data, stores the parity bits in the parity memory array and stores the a set of data in the data memory array in such a way that the parity bits in the parity array have the same physical topology as does the set of data the data memory array.

### CROSS-REFERENCE TO RELATED APPLICATIONS

This Utility Patent Application is related to U.S. patent application Ser. No. ______ filed on even date herewith entitled, “ECC FLAG FOR TESTING ON-CHIP ERROR CORRECTION CIRCUIT,” having Docket Number 2005P50741US/1331.214.101, commonly assigned to the same assignee as the present invention, and hereby incorporated by reference.

### BACKGROUND

The present invention relates to an error correction circuit and method. In particular, a system and method are provided for an error correction circuit used in association with a dynamic random access memory (DRAM) system.

Memory systems, such as DRAM systems, have large memory arrays with large numbers of individual memory cells. During fabrication of the memory arrays, or in subsequent packaging of the memory, it is possible for single cell failures to be introduced in the memory. In some cases, introduction of such failures can result in the need to scrap the entire package afterwards.

Consequently, many memory systems utilize error correction circuits (ECC) to compensate for single cell failures in memory arrays. ECC generate parity codes and utilize a parity memory to detect, and in some cases correct, errors or failures in memory cells. In some cases, such ECC are built directly onto a memory chip in order to achieve superior quality for a customer.

Typically, memory chips are tested after fabrication and assembly to determine whether they are operating properly. In cases where ECC are integrated into the memory chip, testing of these memory systems can become cumbersome. In some cases, a first test pass is done to test the data memory and a second test pass is needed to test the parity memory associated with the ECC. Essentially testing the memory chip twice in this way, takes up valuable test time.

For these and other reasons, there is a need for the present invention.

### SUMMARY

One aspect of the present invention provides a memory system with a data memory and a control circuit. The data memory has multiple memory segments, including a data memory array and a parity memory array. The control circuit is configured to receive a set of data having a plurality of bits, at least some of which are restricted so that they have the same state. The control circuit generates parity bits from the set of data, stores the parity bits in the parity memory array and stores the a set of data in the data memory array in such a way that the parity bits in the parity array have the same physical topology as does the set of data the data memory array.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated, as they become better understood by reference to the following detailed description. The elements of the drawings are not necessarily to scale relative to each other. Like reference numerals designate corresponding similar parts.

FIG. 1 illustrates a tester coupled to a memory chip with error correction circuitry.

FIG. 2 illustrates a portion of data memory system utilizing a modified error correction code in accordance with one embodiment of the present invention.

FIG. 3 is a table illustrating an error correction code used in a data memory system.

FIG. 4 is a table illustrating a modified error correction code used in a data memory system in accordance with one embodiment of the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

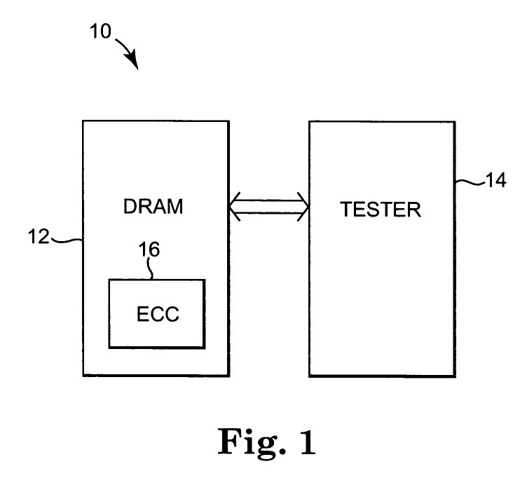

FIG. 1 illustrates a block diagram of memory system 10 in accordance with one embodiment of the present invention. Memory system 10 includes memory chip 12, which is illustrated coupled to memory tester 14. Memory chip 12 includes a plurality of memory arrays. Furthermore, memory chip 12 includes error correction circuit (ECC) 16 built directly onto the memory chip 12. In one embodiment, memory chip 12 is a dynamic random access memory (DRAM) chip.

In operation, tester 14 is used to test operability of memory chip 12. Typically, during a single test pass, data is written to and then read from the various memory arrays within memory chip 12. Tester 14 can then determine the operability of the memory chip 12 after the single test pass to determine information about chip 12, such as whether or not there were failures within memory chip 12.

In one embodiment, ECC 16 uses so-called Hamming codes to detect and correct errors internally to memory chip 12. During a write operation, DQ data from a DQ bus is received in memory chip 12 and stored in a main memory array. Control circuitry within ECC 16 also calculates parity bits from this DQ data using exclusive or (“XOR”) logic functions. These parity bits are then stored within a separate parity memory array. Then, during a read operation, this stored parity data is combined with the corresponding DQ data read from the main memory array (again via XOR gates) to detect and correct errors in the DQ data before it is sent to the DQ bus.

For most memory tests performed by tester 14, the specific physical data topology within the various memory arrays of memory chip 12 is an important parameter of the testing. Each of the memory arrays within memory chip 12 has a plurality of rows and columns, the intersection of which define memory cells. Each memory cell within the various memory arrays is configured to store a bit, which is either a “zero” or a “one”. The collection of physical zeros and ones relatively located in the memory cells of a memory array can be referred to as the physical data topology of the memory array.

When memory chip 12 is tested, it can be useful if each of the various memory arrays within chip 12 have the same physical data topology. In other words, if a first memory array with chip 12 has all physical ones in each of the memory cells of the array, in some cases it is useful if all the remaining memory arrays within chip 12 also have this same physical data topology, that is, all remaining memory arrays also all have all physical ones in each of the memory cells of each array. Similarly, if the first memory array has physical ones and physical zeros alternated in every other column of each row of the array, it is useful in some applications if all the remaining memory arrays within chip 12 also have this same physical topology.

For example, a retention test for memory chip 12 would control the DQ data in order to write all physical ones into every cell of each of the data memory arrays in order to test the retention of the charge in each memory cell. To provide the same test coverage in the main data memory arrays as well as in the parity memory arrays, physical ones would also have to be driven into the parity memory arrays. The parity bits that will be generated by ECC 16 from the DQ data, however, will not necessarily similarly drive all ones into the associated parity memory array. If arbitrary ECC mapping is used, this will lead to some memory cells in the parity memory having physical zeroes in the parity array and some having physical ones.

Thus, when a retention test is performed on such a system with arbitrary ECC mapping, those memory cells with the physical zeros in the parity memory array will escape the retention test. In this case, the physical data topology in each of the data memory arrays will not necessarily be the same as the physical data topology in the parity memory array.

In such situations where the physical data topology of the data memory arrays is different than the physical data topology in the parity memory array, some tests by tester 14 will then need separate access to the parity memory array. If direct access from the external DQ bus to the parity memory array is made, then this will essentially test the memory chip 12 twice, causing time delays in testing.

One embodiment of the present invention, however, restricts the DQ data used in testing memory chip 12, and also specifically defines the ECC mapping such that physical data topology of the data memory arrays is replicated exactly in the parity array. This replication of the physical data topology in each of the data memory arrays, as well as the parity memory array allow for a one-pass test of all memory arrays together, thereby increasing efficiency in memory testing.

In order to ensure that the same physical data is written to the parity array as is written to the main data array using the ECC, it may not be possible to use all possible combinations of DQ data. However, memory testing is often performed in a DQ-compressed fashion. In other words, rather that writing all possible combinations of DQ data bits into the data memory arrays of memory chip 12, certain of the DQ data bits are simply copied from other DQ data bits.

For example, if redundant elements on the chip always replace several DQs together then one does not lose vital information by compressing the pass/fail information of these DQs together. Compressed testing allows for certain DQs to always have the same data without losing test coverage or pass/fail information. When the allowed combinations of DQ data are restricted then it is possible to have perfect mapping of physical data topologies from the main array to the parity array using the normal XOR operations of the ECC circuit.

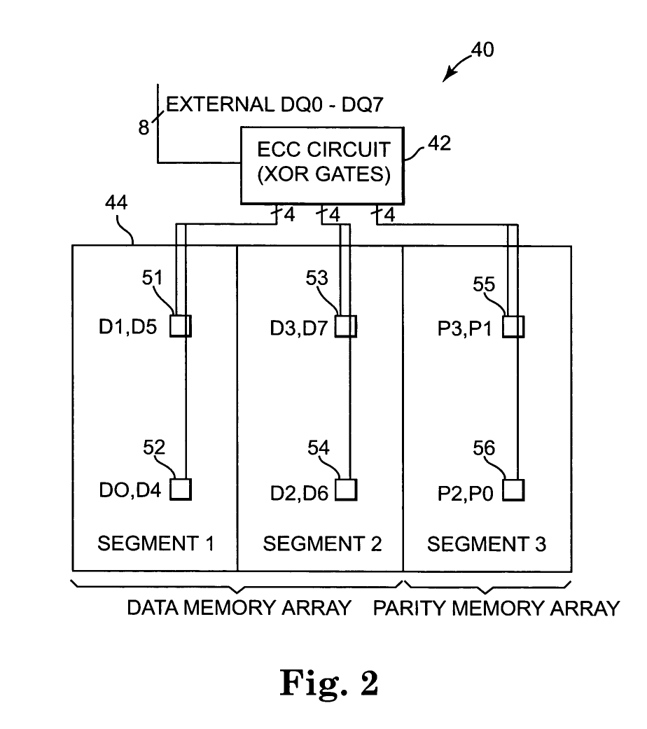

FIG. 2 illustrates a portion of a memory system 40, such as memory chip 12 in FIG. 1. Memory system 40 includes external DQ data (eight bits D₀-D₇ in the illustration), which enters ECC circuit 42. ECC 42 then generates parity bits in accordance with a DQ mapping code configured within ECC 42, typically using a combination of XOR gates. The DQ data and parity data is stored within memory array 44. In one case, memory array 44 is broken into first, second and third segments. The first segment and the second segment are data memory arrays for storing the DQ data and the third segment is a parity memory for storing the generated parity data. Each array segment contains a plurality of memory cells at the intersection of rows and bit lines. Two such memory cells are illustrated by each of first-sixth memory cell pairs 51-56

As indicated above, the bit definitions of the DQ data can be restricted during testing of memory systems in order to accommodate more efficient testing. This is sometimes referred to as restricting the degrees of freedom of the DQ data. In one example, all physical data topologies in memory array 44 can be achieved by varying only two bits of the DQ data independently. For example, physical data topologies of data memory array 44 can be controlled using:
D₀=D₁=D₂=D₃=DATA_{A} (Equation 1)
D₄=D₅=D₆=D₇=DATA_{B} (Equation 2),
where D₀-D₇ are the eight bits of data within a DQ data stream.

Data within memory array 44 is arranged such that each of the four DQ bits carrying the same data are associated with a specific physical element in the first and second segments of memory array 44 (that is, a specific intersection of word line and column select line) which is copied identically (same physical symmetry and layout) at four locations on the chip. For example, in FIG. 2 first and second memory cell pairs 51 and 52 are located at two locations within the first segment of memory array 44. Similarly, third and fourth memory cell pairs 53 and 54 are located at the same two relative locations within the second segment of memory array 44. In the illustrated example, the identical bits D₀=D₁=D₂=D₃=DATA_{A} are located in the first part of each of memory cell pairs 51-54 and the identical bits D₄=D₅=D₆=D₇=DATA_{B} are located in the second part of each of memory cell pairs 51-54.

Furthermore, in order to get the exact same physical topology in the parity array of the third segment of data memory 44, fifth and sixth memory cell pairs 55-56 are also located at the same two relative locations within the third segment of memory array 44. To ensure the same physical topology, the parity bits in fifth and sixth memory cell pairs 55-56 must align with those in memory cell pairs 51-54. In this way, in the illustration, two of the parity bits equal DATA_{A} and the two others equal DATA_{B}.

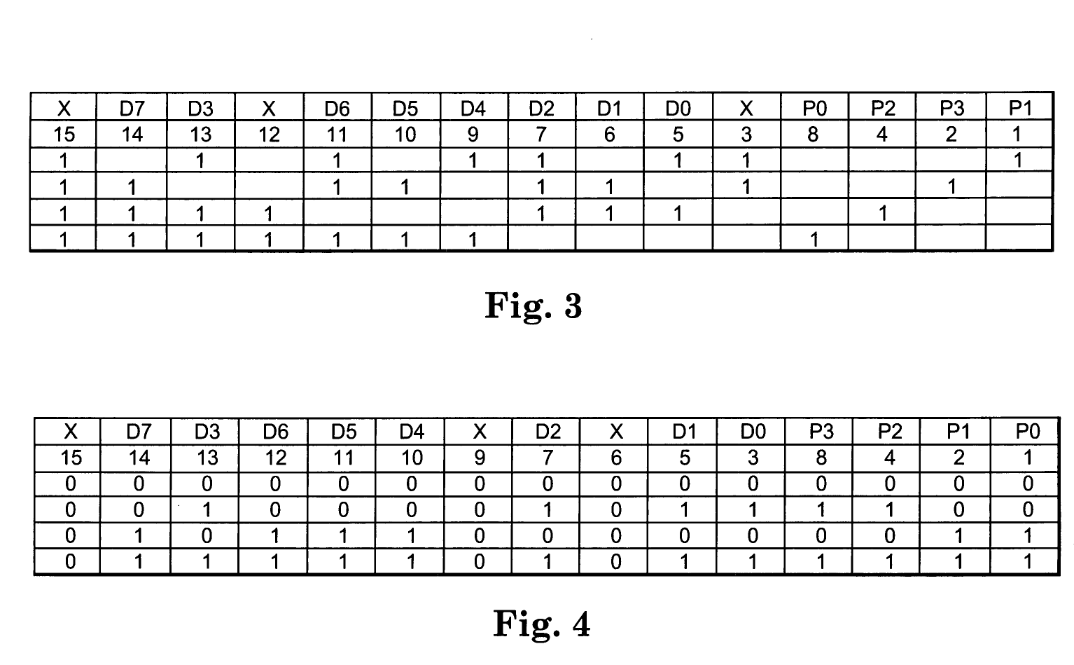

One example of an application in a test on a memory chip 12 is illustrated with reference to the Hamming code in FIG. 3. FIG. 3 illustrates an example of arbitrary DQ mapping. Essentially, the Hamming code is configured to detect and correct bit errors in the DQ data by inserting error correction or parity bits into the DQ data stream, thereby increasing the overall number of bits. The parity bits can be examined after data is extracted to determine whether a bit error has occurred.

The Hamming code illustrated in FIG. 3, can be considered a modified (15,11) Hamming code or an (8,12) Hamming code. In this case, an 11-bit data stream has four parity bits inserted to bring the total number of bits to 15. However, since most DQ data streams have 8 bits, 3 of the eleven are not used (indicated by the “X” in the columns), and thus, the code will be referred to as an (8,12) Hamming code.

The second row in the table of the (8,12) Hamming code lists the bit locations 1-15. As indicated, after insertion of the four parity bits, there are 15 total bit locations. The first row in the table lists the bit definitions. Data bits from an 8-bit DQ data stream are indicated with D₀, D₁, D₂, D₃, D₄, D₅, D₆, and D₇. The three unused data bits are indicated with an “X”. The four parity bits are indicated with P₀, P₁, P₂, and P₃. As may be apparent, the parity bits are located in each of the locations that are powers of 2, or at locations 2ⁿ, such that they will be in positions 1, 2, 4, and 8.

In one case, a general ECC algorithm within EEC 16 works according to this arbitrary DQ mapping table in FIG. 3. Each parity bit calculates the parity for some of the bits in the code word. The position of the parity bit determines the sequence of bits that it alternatively checks and skips, starting with the position of the parity bit.

In this example, for P₁ the sequence of bits will be to check every other one bit location, that is, check one, skip one, check one skip one, etc. In the third row of the table, a “1” is placed under the data bit that is checked with parity bit P₁. For P₃, the sequence of bits will be to check every other two bit locations, that is, check two, skip two, check two skip two, etc. Again, in the fourth row of the table, a “1” is placed under the data bit that is checked with parity bit P₃. For P₂, the sequence of bits will be to check every other four bit locations, that is, check four, skip four, check four skip four, etc. Again, in the fifth row of the table, a “1” is placed under the data bit that is checked with parity bit P₂. Finally, for P₀, the sequence of bits will be to check every other eight bit locations, that is, check eight, skip eight, check eight skip eight, etc. In the fifth row of the table, a “1” is placed under the data bit that is checked with parity bit P₀.

For a write operation, the parity bit is then set to 1 if the total number of ones in the sequence of positions is odd and will be set to 0 is the total number of ones in the sequence of positions is even. This may be accomplished by performing an XOR operation on the data bits in the sequence associated with each parity bit (excluding the parity bit from the XOR operation). The result of the XOR operation determines the value of the associated parity bit.

Then, for a read operation, a XOR operation of the data bits along with the associated parity bit determines whether there is bit failure. If the result of the XOR operation is zero, then there was no bit failure. Where the result is not zero, however, it indicates a failure or error code for the data bit associated with the parity bit. This error code triggers a correction of the associated DQ data bit.

In this example using arbitrary DQ mapping, the physical data in the parity array will not match the one in the main array. Using memory system 40 in FIG. 2 and equations 1 and 2 above where DATA_{A}=1 and DATA_{B}=0 for example, produces a one followed by a zero in each of memory cell pairs 51-54 (data memory), but a zero followed by a one in each of memory cell pairs 55-56 (parity memory)

The DQ mapping within ECC circuit 42 can be arranged, however, such that the physical data in the data memory array will match the physical data in the parity memory array. One example of such an application using one of these arranged DQ mappings is illustrated with reference to the table in FIG. 4. Again, the 15 bit positions are illustrated across the second row and the bit definitions for the ECC circuit are each illustrated across the first row. Rows three through six of the table represent all possible data values of DATA_{A} and DATA_{B}.

The combination of the particular bit positions (1-15) through XOR operation is done the same way as explained above in reference to the table in FIG. 3. In this case, a static signal (X=0) is applied to all unused ECC positions, which in this example is bit positions 6, 9, and 15. In addition, the assignment of DQ data bits to the ECC positions is changed such that for all combinations of DATA_{A} and DATA_{B}:
P₀=P₁=DATA_{B}; and
P₂=P₃=DATA_{A}.

In this way, when ECC circuit 42 is designed in accordance with the bit assignments in FIG. 4, and equations 1 and 2 above are used, then D₀=D₁=D₂=D₃=P₂=P₃ and D₄=D₅=D₆=D₇=P₀=P₁. By associating the parity bits P₀, P₁, P₂ and P₃ with the correct physical elements in the parity array, the parity array has the exact same physical data topology as the main array when writing through the ECC circuit 42.

On skilled in the art will understand that the associations of the parity bits P₀, P₁, P₂ and P₃ with the physical elements in the parity array in FIG. 4 is just one example of how the parity bits can be associated to ensure that the parity array has the exact same physical data topology as the main array when writing through the ECC circuit 42. Other combinations are possible as well. Also, in any case, the physical topologies in the parity array and data memory are correct whether memory chip 12 is tested with or without DQ compression, as long as equations 1 and 2 are fulfilled. With this arranged DQ mapping, no test time overhead for the writing of topologically correct data to the parity memory array is incurred. This results in efficient testing.

Although specific embodiments have been illustrated and described herein, it will be appreciated by those of ordinary skill in the art that a variety of alternate and/or equivalent implementations may be substituted for the specific embodiments shown and described without departing from the scope of the present invention. Thus, this application is intended to cover any adaptations or variations of the specific embodiments discussed herein. Therefore, it is intended that this invention be limited only by the claims and the equivalents thereof.

What is claimed is:

1. A memory system comprising:
a data memory with multiple memory segments, including a data memory array and a parity memory array;
a control circuit configured to receive a set of data having a plurality of bits, at least some of the bits having restricted states; and
means for generating parity bits from the set of data, for storing the parity bits in the parity memory array, and for storing the a set of data in the data memory array in such a way that the parity bits in the parity array have a physical data topology that is the same as a physical data topology of the set of data in the data memory array.

2. The memory system of claim 1, wherein the control circuit is further configured to detect and correct any error that occurred in storing the set of data.

3. The memory system of claim 1, wherein the parity bits are generated according to a modified Hamming code.

4. The memory system of claim 1, wherein the parity bits from the parity memory array are combined with the set of data from the data memory array according to a modified Hamming code in order to determine whether any error occurred in storing the set of data.

5. The memory system of claim 1, wherein the restricted states are such that one half of the plurality of bits of the set of data are a zero state and one half of the plurality of bits of the set of data are a one state having, and wherein one half of the parity bits generated from the set of data are a zero state and one half of the parity bits generated from the set of data are a one state.

6. The memory system of claim 1, wherein the restricted states are such that all of the plurality of bits of the set of data are a one state and all of the parity bits generated from the set of data are a one state.

7. A system tester comprising:
a testing mechanism;
a memory chip coupled to the testing mechanism, the memory chip further comprising:
a data memory array configured to hold data;
an error control circuit configured to receive the data and to generate parity bits therefrom;
a parity memory configured to hold the parity bits;
the error control circuit further configured to receive and combine the data from the data memory array and the parity bits from the parity memory to determine whether an error occurred in the data; and
wherein the error control circuit is further configured to generate the parity bits from the data in such a way that the parity bits in the parity memory have a physical data topology that is the same as a physical data topology of the data in the data memory array.

8. The system tester of claim 7, wherein the testing mechanism is configured to make a test pass on the memory chip such that operability of the data memory array is tested during the test pass.

9. The system tester of claim 8, wherein after the test pass, the parity bits in the parity memory have the same physical data topology as the data in the data memory array.

10. A memory device comprising:
a data memory configured to store DQ data in a physical data topology of the data memory;
an error correction circuit configured to receive the DQ data and to generate parity bits from the DQ data; and
a parity memory configured to receive and hold the parity bits in a physical data topology of the parity memory;
wherein the error correction circuit is configured with arranged DQ mappings such that the physical data topology of the data memory is the same as the physical data topology of the parity memory.

11. The memory device of claim 10, further including a tester coupled to the data memory and configured to run a test on the data memory to determine whether it is operable.

12. The memory device of claim 11, wherein error correction circuit configured with arranged DQ mappings employs a modified Hamming code to generate parity bits in such a way that the physical data topology of the data memory is the same as the physical data topology of the parity memory.

13. The memory device of claim 12, wherein degrees of freedom of the DQ data is restricted during the test.

14. The memory device of claim 13, wherein the DQ data is restricted during the test such that only two bits of the DQ data are varied independently.

15. An error detection system comprising:
a tester circuit;
a data memory configured to receive and to store a set of data;
a parity memory configured to receive and to store parity bits; and
an error correction circuit configured to generate the parity bits by logically combining selected combinations of bits from the set of data in such a way that when the set of data is stored in the data memory and the parity bits are stored in the parity memory the data memory and the parity memory have the same physical data topology.

16. The error detection system of claim 15, wherein the logical combination of selected combinations of bits from the set of data to generate the parity bits is controlled according to a modified Hamming code.

17. The error detection system of claim 16, wherein degrees of freedom of the set of data is restricted such that only two bits of the set of data are varied independently.

18. A method for testing a memory device, the method comprising:
writing a set of data into a data memory such that the set of data in the data memory has a physical data topology;
writing the set of data to an error correction circuit configured to receive the set of data;
generating parity bits with the error correction circuit using the set of data; and
storing the parity bits into a parity memory in such a way that the parity bits in the parity memory has a physical data topology that is the same as the physical data topology of the set of data in the data memory.

19. The method of claim 18, wherein generating the parity bits includes logically combining certain combinations of bits from the set of data.

20. The method of claim 19, wherein the logically combining step further includes combining the bits from the set of data according to a modified Hamming code.

21. A method testing a memory chip with on-chip error correction circuit comprising:
providing a memory chip;
writing a set of data in a data memory of the memory chip such that the set of data in the data memory has a physical data topology;
writing the set of data to an error correction circuit that is configured on the memory chip;
generating parity bits with error correction circuit using the set of data;
storing the parity bits into a parity memory in such a way that the parity bits in the parity memory has a physical data topology that is the same as the physical data topology of the set of data in the data memory;
logically combining the set of data from the data memory with the parity bits to determine whether an error occurred within the set of data written into the data memory; and
correcting errors that occurred within the set of data written into the data memory.

22. The method of claim 21, further including logically combining the set of data from the data memory with the parity bits using a modified Hamming code.

23. A method for testing a memory device, the method comprising:
controlling a set of data including a plurality of bits so that only two bits of the set of data are varied independently;
writing a set of data into a data memory such that the set of data in the data memory has a physical data topology;
writing the set of data to an error correction circuit configured to receive the set of data;
generating parity bits with the error correction circuit using the set of data; and
storing the parity bits into a parity memory in such a way that the parity bits in the parity memory has a physical data topology that is the same as the physical data topology of the set of data in the data memory.
